(19) United States
(12) Patent Application Publication
(10) Pub. No.: US 2023/0101133 A1
(43) Pub. Date: Mar. 30, 2023

(54) END-TO-END CAMERA ARCHITECTURE FOR DISPLAY MODULE

(71) Applicant: Google LLC, Mountain View, CA (US)

(72) Inventors: Sangmoo Choi, Palo Alto, CA (US); Chang Ju Kang, Cupertino, CA (US)

(21) Appl. No.: 17/785,751

(22) PCT Filed: Oct. 6, 2020
(86) PCT No.: PCT/US2020/054440

§ 371 Date: Jun. 15, 2022

Related U.S. Application Data
(60) Provisional application No. 62/949,297, filed on Dec. 17, 2019.

(51) Int. Cl. H04M 1/02; H04N 23/90; H04N 5/265; H10K 50/84; H01L 23/538; G06F 1/16

(52) U.S. Cl. CPC H04M 1/0264; H04N 23/90; H04N 5/265; H04M 1/0268; H01L 51/5237; H01L 23/5387; G06F 1/1641; G06F 1/1686; H01L 2251/5338

(57) ABSTRACT

A display module is described that has two or more front-facing camera modules at opposing edges of a computing device. Using images acquired by both camera modules, when a user is looking directly at the display, it is possible to generate an image of the user as though he/she was looking directly toward the lens of a camera module.

### TECHNICAL FIELD

The subject matter described herein relates to a display module for a computing device having two front-facing camera modules and methods for using the same.

### BACKGROUND

Conventional mobile devices typically include a single front-facing camera which can be used for video chatting and selfies, for example. Such cameras are often located outside a display active area of the device's display module, such as in the display's bezel or a notch or aperture near the edge of the display active area. When a user looks at the center of the display screen, e.g., during video chatting, the front-facing camera captures the image of the user at an angle, rather than looking directly into the camera. Such images are often not desirable, such as during video chats.

One solution to ensure that the user looks directly at the front facing camera when directly facing the display is to place the camera at the center of the display. However, because cameras typically require an unobstructed line of sight to their subject to provide clear images, such as solution involves making an aperture in the center of the display active area, which is not desirable.

### SUMMARY

The disclosure features a display module having two (or more) front-facing camera modules at opposing edges of a computing device. Using images acquired by both camera modules, when a user is looking directly at the display, it is possible to generate an image of the user as though he/she was looking directly toward the lens of a camera module.

In one aspect, a display module is described that includes multiple layers including a display panel including a display active area and a back cover bonded to the display panel. The display module further includes a first aperture on a first end of the display active area of the display panel. The first aperture is configured to receive a first camera module. The display module further includes a second aperture on a second end of the display active area of the display panel. The second aperture is configured to receive a second camera module. A first layer of the multiple layers is designed to fold around the back cover. The display module includes a third aperture created by punching two or more layers of the multiple layers when the first layer is folded around the back cover such that the third aperture aligns with the second aperture. The third aperture is designed to receive a second camera module. Note that the phrase “configured to receive” may in some implementations described herein mean “configured for use with”. That is, in some examples, any of the first, second and third apertures may not necessarily “physically” receive a portion of a camera module within the aperture itself, but may instead provide a transparent window through which light may travel such that said light may reach a camera module. The second camera module referred to with reference to the second aperture may be the same second camera module referred to with reference to the third aperture. That is, the same, second, camera module may be configured to receive light that has been transmitted through both the second and third apertures.

In some implementations, one or more of the following can be implemented either individually or in any feasible combination. The first layer is the display panel. In one example, the multiple layers further include a substrate bonded to the display panel. The two or more layers that are punched to create the third aperture include the display panel, the back cover, and the substrate. The substrate is a film. In another example, the two or more layers that are punched to create the third aperture include a portion of the display panel and the back cover. The multiple layers further include a substrate bonded to the display panel. The two or more layers that are punched to create the third aperture exclude the substrate and another portion of the display panel located between the substrate and the back cover.

In one instance, the display module further includes a display driver integrated circuit that facilitates the display active area of the display panel. The third aperture is between the display driver integrated circuit and a portion of the display panel that is folded. In another instance, the display module further includes a display driver integrated circuit that facilitates the display active area of the display panel, and a flexible printed circuit board connected to the display panel via a bonding pad. The third aperture in such instance is between the display driver integrated circuit and the bonding pad.

In another example, the first layer is a substrate bonded to the display panel. The substrate is a film. In one instance of such example, the multiple layers further include a substrate bonded to the display panel, and the two or more layers that are punched to create the third aperture include the display panel, the back cover, and the substrate. In another instance, the two or more layers that are punched to create the third aperture include a portion of the substrate and the back cover. The two or more layers that are punched to create the third aperture exclude another portion of the substrate and the display panel.

The display module further includes a display driver integrated circuit that facilitates the display active area of the display panel. In some examples, the display driver is located on the substrate, and the third aperture is between the display driver integrated circuit and a portion of the display panel that is folded. In other examples, the display driver is located on the substrate, the substrate is connected to a flexible printed circuit board via a bonding pad, and the third aperture is between the display driver integrated circuit and the bonding pad.

In another aspect, an apparatus is described that includes a first aperture on a first end of a display active area of a display panel and a second aperture on a second end of the display active area of the display panel. The first aperture is configured to receive a first camera module, and the second aperture is configured to receive a second camera module. Each of the first and second ends of the display active area have an emissive pixel density that is lower than the emissive pixel density in other areas of the display active area. Optional features of one aspect may be combined with any other aspect where feasible. Also, aspects described herein may be combined with other aspects where feasible.

The subject matter described herein provides many advantages. For example, the structures of the display module described herein permit two or more camera modules to be fitted within a display active area of the display, which in turn allows creation of an image of a user looking away from the camera modules toward the center of the screen as though the user was looking toward a camera module. Such images are typically more desirable than images where the user is not looking directing into the camera module, especially in during activities like video chatting.

The details of one or more variations of the subject matter described herein are set forth in the accompanying drawings and the description below. Other features and advantages of the subject matter described herein will be apparent from the description, drawings, and claims.

### DESCRIPTION OF DRAWINGS

FIG. 1 is a schematic diagram of an example device having a display module with two front-facing camera modules, and a data processing apparatus.

FIG. 2 is a cross-sectional view of a portion of the display module shown in FIG. 1 at and around an aperture (“camera window”) configured to accommodate one of the camera modules (here, top aperture of FIG. 1 to receive the top camera module of FIG. 1) through the active area of the display.

FIG. 3A is a front view of an example display module including a display panel with two front facing camera modules and an interface module that is coupled to the display panel and is to be folded (i.e. bent) underneath a portion of the display panel.

FIG. 3B is a rear view of the display module shown in FIG. 3A, and shows the interface module of FIG. 3A that has been folded and placed underneath a portion of the display panel.

FIG. 4A is a front view of another example of a display module including the display panel shown in FIG. 3A and an alternative interface module that is coupled to the display panel and is to be folded underneath a portion of the display panel.

FIG. 4B is a rear view of the display module shown in FIG. 4A, and shows the interface module of FIG. 4A that has been folded and placed underneath a portion of the display panel.

FIG. 5 is a cross-sectional view of an edge portion of an example display module at a location where a front-facing camera module is to be placed by making/punching a hole.

FIGS. 6A-6B show examples of an edge portion of the display module shown in FIGS. 3A and 3B, each having different configurations for accommodating a front-facing camera module.

FIGS. 7A-7B show examples of an edge portion of the display module shown in FIGS. 4A and 4B, each having different configurations for accommodating a front facing camera module.

FIG. 8A shows a front view of yet another example of a display module including the display panel with two front facing camera modules and another alternative interface module that is coupled to the display panel and is to be folded underneath a portion of the display panel.

FIG. 8B shows a rear view of the display module shown in FIG. 8A, and shows the interface module of FIG. 8A that has been folded and placed underneath a portion of the display panel.

FIG. 9A is a front view of another example of the display module including the display panel and another alternative interface module that is coupled to the display panel and is to be folded underneath a portion of the display panel.

FIG. 9B is a rear view of the display module of FIG. 9A, and shows the interface module of FIG. 9A that has been folded and placed underneath a portion of the display panel.

FIG. 10 is a cross-sectional view of an edge portion of another example display module at a location on the display module where a front-facing camera module is to be placed by making/punching a hole.

FIGS. 11A-11B show examples of an edge portion of the display module shown in FIGS. 8A and 8B, each having different configurations for accommodating a front-facing camera module.

FIGS. 12A-12B show examples of an edge portion of the display module shown in FIGS. 4A and 4B, each having different configurations for accommodating a front facing camera module.

FIGS. 13A-13D shows an example display module with a display panel having areas of differing pixel density in areas where front-facing camera modules are placed.

Like reference symbols in the various drawings indicate like elements.

### DETAILED DESCRIPTION

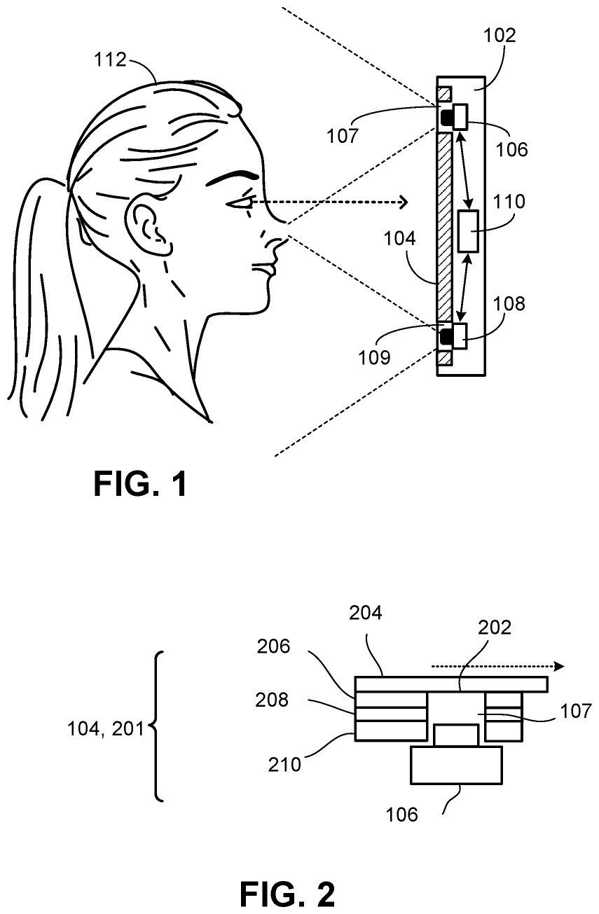

FIG. 1 illustrates a computing device 102 having a display module 104 with two front-facing camera modules 106 and 108, and a data processing apparatus 110 (e.g., including one or more processing units, such as one or more CPUs and/or GPUs). The computing device 102 can be a smart phone, as shown. In other implementations, the computing device 102 can be a phablet computer, a tablet computer, a laptop, a desktop computer, any other computing device that uses a display module, and/or any combination thereof.

Display module 104 includes apertures 107 and 109 (also referred to as camera windows) in the display active area (i.e., the portion of the display composed of pixels for generating displayed images) near the top and bottom edges, respectively, of the display active area. Camera modules 106 and 108 are each positioned at a respective aperture and receive light from within a respective field of view transmitted through the respective aperture.

Each of the camera modules 106 and 108 generally includes a lens, control electronics, and an interface such as the camera serial interface (CSI), Ethernet or low-voltage differential signaling (LVDS) for communicating with other components of computing device 102.

When a user 112 participates in an interactive session (e.g., video chat) or takes a selfie using device 102, both the camera modules 106 and 108 simultaneously acquire one or more images of the user 112 (e.g., face of the user 112). For example, when acquiring video footage, each of the camera modules 106 and 108 acquires images at a particular frame rate, for example, from 20 images per second to 120 images per second. When the user 112 looks at the center of the display module 104 (as illustrated), which is typical during such interactive sessions, the images acquired by the camera module 106 are from the perspective of the user 112 looking below at a point the camera module and the images acquired by the camera module 108 are from the perspective of the user 112 looking at a point above the camera module. In other words, neither camera module acquires images of the user looking directly into the lens of the camera module.

In an interactive session, such as during a video chat, it is generally desirable that the image of a participant presented on the display appear as though that person is looking directing into the lens of the camera module, so that the participants appear as though they are interacting face-to-face. However, for devices having only a single front-facing camera module offset to an edge of the display, the camera module captures images of a user from an angle when the user is looking at the display. For example, if the computing device 102 had only the camera module 106 (and not the camera module 108), the image acquired would show the user 112 as looking below rather than toward the entity in the interactive session. If the computing device 102 had only the camera module 108 (and not the camera module 106), the acquired image would show the user 112 as looking above rather than toward the entity.

Similarly, when taking a selfie photograph, people often prefer images taken with the subjects looking directly into the lens of the camera module. However, users often tend to look at the center of the device's display while taking selfies.

Providing front-facing camera modules 106 and 108 at opposite edges of device 102, allows the device to simultaneously acquire images from both sides of the subject. With these images, the data processing apparatus 110 receives those two images from the two camera modules, and process those images to generate a processed image that is a composite of the two actual images and appears as though the user is looking directly into the lens of a camera module.

Similarly, in an interactive session using video images, camera modules acquire images over time at a frame rate and the data processing apparatus 110 processing simultaneous frames from the two camera modules to generate a composite video and transmits the composite video stream to the entity communicating with the user 112. In the composite video, the user appears as though the user 112 as looking toward the display rather than above or below the display.

While computing device 102 has two front-facing camera modules 104 and 108, in some implementations, more generally computing devices can have additional front-facing camera modules that are also coupled to the data processing apparatus 110. Further, in some implementations, the locations of the camera modules 106, 108 and/or other camera modules can vary. For example, while camera modules 106 and 108 are located at a top edge and bottom edge of the display panel, camera modules can be located on the side edges of the display in certain implementations.

FIG. 2 illustrates a cross-sectional view of an edge 201 of the display module 104 with aperture 107 and the camera module 106. The display module 104 is a multilayer device that includes a display panel 208 (e.g., an organic light emitting diode (OLED) panel), one or more films 206 (e.g., a polarizer, a quarter wave plate) stacked on top of the panel. Module 104 also includes a back cover 210 and a cover glass 204 on top of the films 206. Aperture 107 extends through back cover 210, panel 208, and films 206, but cover glass 204 extends over the aperture providing a window 202 for the camera module 106. In some implementations, the back cover 210 can include additional cushion sheets. The aperture 107 can be created within the display module 104 by punching or making a hole through the film 206, the panel 208, and the back cover 210.

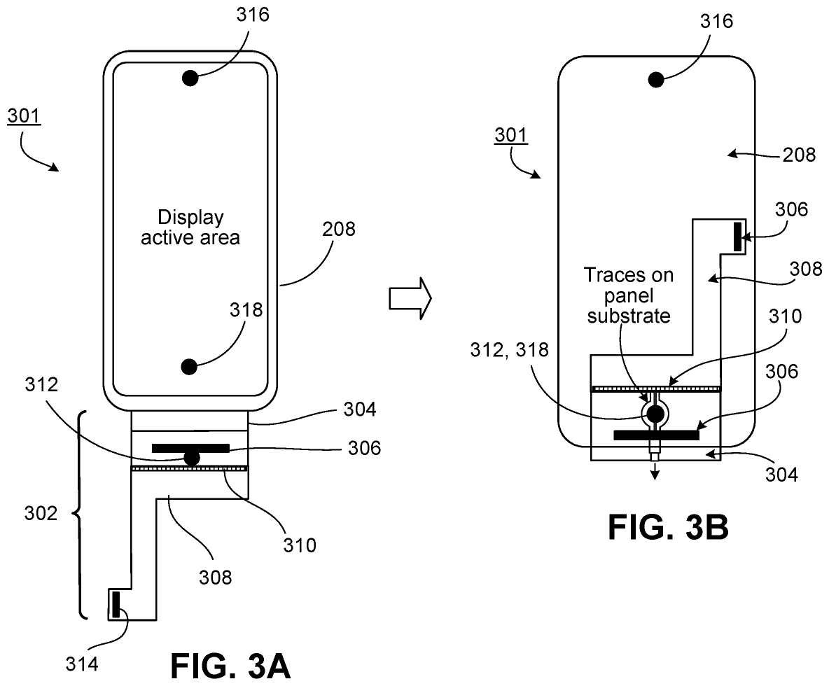

Generally, display panels interface with an interface module that includes additional components to generate and deliver signals for controlling pixels in the display panel. For example, display modules can include integrated circuits attached to the display panel via a flexible printed circuit board that can be folded (i.e. bent) behind the display when the module is installed in a computing device. FIG. 3A illustrates a front view of a display module 301 that includes a panel 208 with a top aperture 316 and a bottom aperture 318 for corresponding camera modules (not shown in this drawing). The display module 301 also includes an interface module 302 at the bottom edge of the display module 301. The interface module 302 can be an interface board, which includes a panel bending area 304 for folding the interface module 302 behind the display panel 308. The panel bending area 304 is unfolded in the configuration shown. The interface module 302 further includes a display driver integrated circuit (IC) 306, a flexible printed circuit board (PCB) 308, and a bonding pad 310 coupling the panel area that includes the display driver IC 306 with the flexile PCB 308. The portion of interface module 302 that includes the display driver IC 306 further includes an aperture 312 positioned and sized to receive the front facing camera module that is installed at aperture 318. The flexible PCB 308 also has a connector 314 to connect the display module 301 with other components of the computing device in which it is installed (e.g., for electrical power and control signals from data processing units in the device).

FIG. 3B is a rear view of the display module 301, and shows the interface module 302 that has been folded and placed underneath a portion of the display panel 208. As the aperture is punched when the interface module 302 is folded, the aperture 312 necessarily overlaps with the aperture 318.

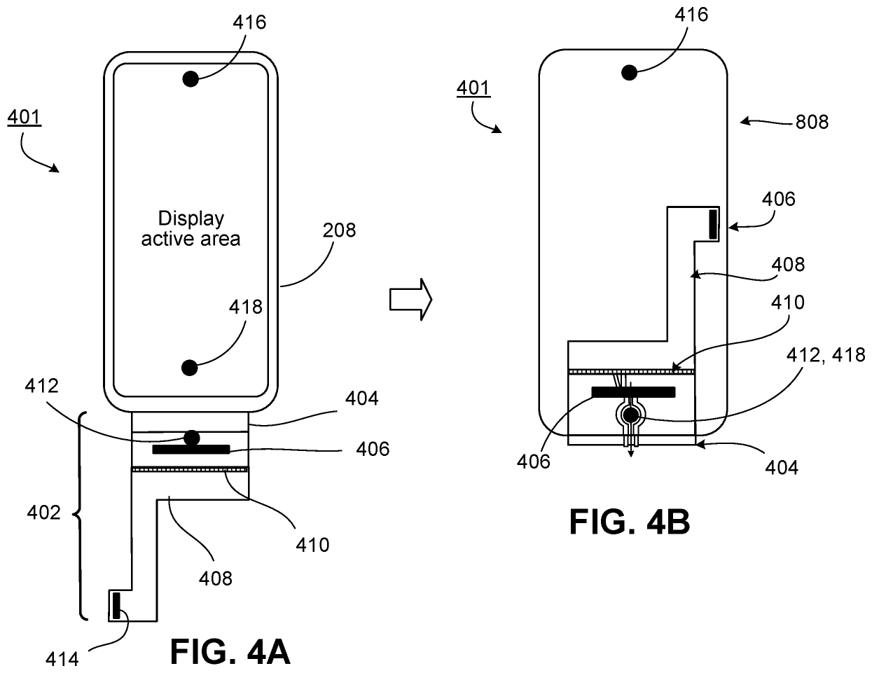

FIG. 4A is a front view of another example display module 401 including the display panel 208 that has apertures 416 and 418 to accommodate camera modules (not shown in the drawing) and an interface module 402 (which is an alternate to the interface module 302). The interface module 402 includes a panel bending area 404 (which is same as or similar to the panel bending area 304), which is not yet folded in the shown configuration. The second structure 402 further includes a display driver integrated circuit (IC) 406 (which is same as or similar to the display driver IC 306), a flexible printed circuit board (PCB) 408 (which is same as or similar to the flexible PCB 308), a bonding pad 410 (which is same as or similar to the bonding pad 310) coupling the panel area that includes the display driver IC 406 with the flexile PCB 408. The panel area that includes the display driver IC 406 further includes an aperture 412 configured to receive the camera module 108. In this implementation, the aperture 412 is above the display driver IC 306 (unlike the aperture 312 which is below the display driver IC). The flexible PCB 308 has a connector 414 (which is same as or similar to the connector 314) to connect the display module 401 with other components of the computing device in which it is installed (e.g., for electrical power and control signals from data processing units in the device).

FIG. 4B is a rear view of the display module 401, and shows the interface module 402 that has been folded and placed underneath a portion of the display panel 208. As the aperture is punched when the interface module 402 is folded, the aperture 412 necessarily overlaps with the aperture 418.

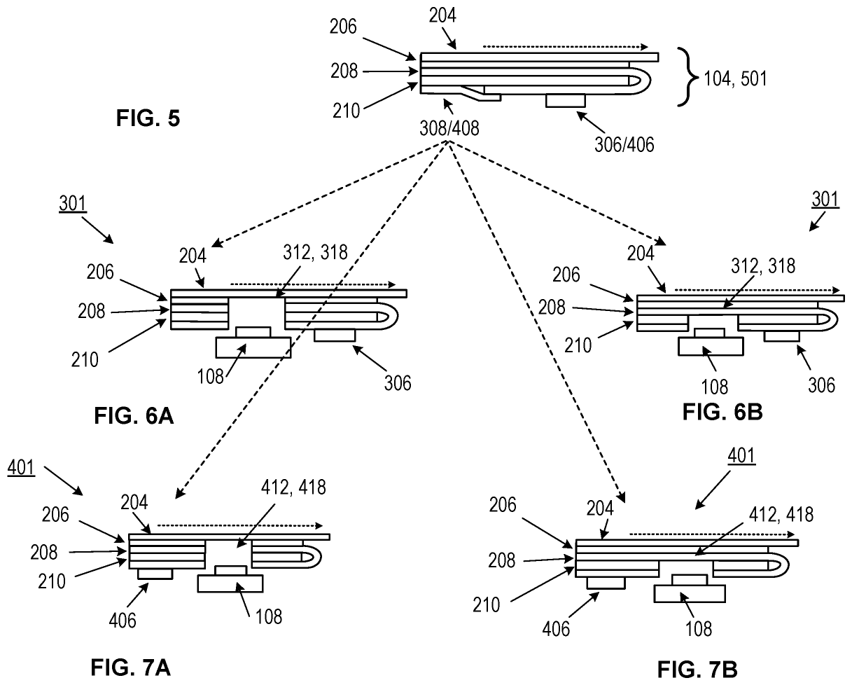

FIG. 5 is a cross-sectional view of an edge portion 501 (which is different from the edge portion 201 as shown in FIG. 2) of the display module 104 at a location where the front-facing camera module 108 is to be placed by making/punching a hole. The punched hole is shown in FIGS. 6A-7B, discussion of which follows.

FIG. 6A shows a cross-sectional view of an edge portion 501 of the display module 301, which has an aperture 312/318 to accommodate the front-facing camera module 108. In this implementation, the aperture 312/318 is punched through the panel 208 as well as the film 206, back cover (which can include additional cushion sheets) 210 and a folded portion of the panel 208.

FIG. 6B shows a cross-sectional view of an edge portion 501 (which is different from the edge portion 201 as shown in FIG. 2) of the display module 301 at a location where the camera module 108 is placed. This variation is for the case where the panel 208 has a high enough transmittance (i.e., transmittance that higher than a correspondence transmittance in the implementation of FIG. 6A by 10% or more, such as 20%, 30%, 40%, or the like) for effective performance of the camera module 108. Such high enough transmittance can be attained by lowering the density of various components (e.g., metallic elements that form pixel circuits, signal lines, power lines, OLED electrodes, and/or the like, and may be arranged in one or more patterns) in part of the display active area where the aperture 312/318 is located. In this variation, the aperture 312/318 is punched only in the back cover (which can include additional cushion sheets) 210 and the folded portion of the panel 208, but not through the main portion of the panel 208.

FIG. 7A shows a cross-sectional view of an edge portion 501 (which is different from the edge portion 201 as shown in FIG. 2) of the display module 401, which has an aperture 412/418 for accommodating the camera module 108. In this variation, an aperture 412/418 is punched through the panel 208, as well as the film 206, back cover (which can include additional cushion sheets) 210, and a folded portion of the panel 208.

FIG. 7B shows a cross-sectional view of an edge portion 501 (which is different from the edge portion 201 as shown in FIG. 2) of the display module 401, which has an aperture 412/418 to accommodate the camera module 108. This variation is for the case where the panel 208 has a high enough transmittance (i.e., transmittance that higher than a correspondence transmittance in the implementation of FIG. 6A by 10% or more, such as 20%, 30%, 40%, or the like) for effective performance of the camera module 108. Such high transmittance can be attained by lowering the density of various components (e.g., metallic elements that form pixel circuits, signal lines, power lines, and OLED electrodes, and/or the like, and may be arranged in one or more patterns) in part of the display active area where the aperture 412/408 is located. In this variation, an aperture 412/418 is punched through only the back cover (which can include additional cushion sheets) 210 and the folded portion of the panel 208, but not through the main portion of the panel 208.

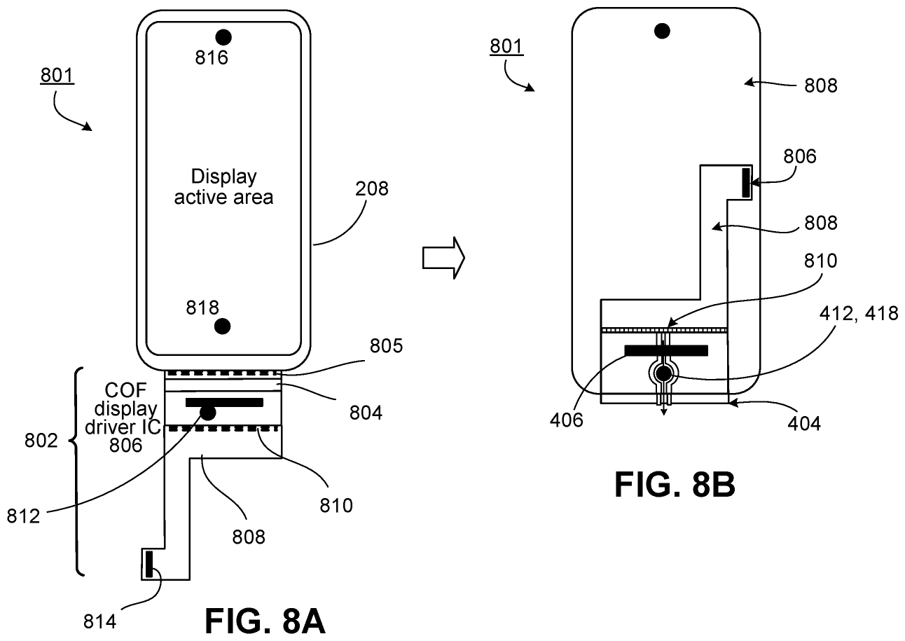

FIG. 8A illustrates a front view of another display module 801 including (a) the display panel 208 with two apertures 816 and 818 designed to accommodate front facing camera modules (not shown in this drawing) and (b) another interface module 802 that is coupled to the display panel 208 and is to be folded underneath a portion of the display panel 208. The interface module 802 includes a film bending area 804, which is not yet folded in the shown configuration. The film bending area 804 is coupled to the panel 208 via a bonding pad 805. The interface module 802 further includes a display driver integrated circuit (IC) 806, a flexible printed circuit board (PCB) 808, a bonding pad 810 coupling the film area that includes the display driver IC 806 with the flexile PCB 808. The film area that includes the display driver IC 806 further includes an aperture 812 configured to receive the camera module 108. In this implementation, the aperture 812 is below the display driver IC 806. The flexible PCB 808 has a connector 314 to connect the display module 801 with other components of the computing device in which it is installed (e.g., for electrical power and control signals from data processing units in the device).

FIG. 8B illustrates a rear view of the display module 801, and shows the interface module 802 that has been folded and placed underneath a portion of the display panel 208. As the aperture is punched when the interface module 802 is folded, the aperture 812 necessarily overlaps with the aperture 818.

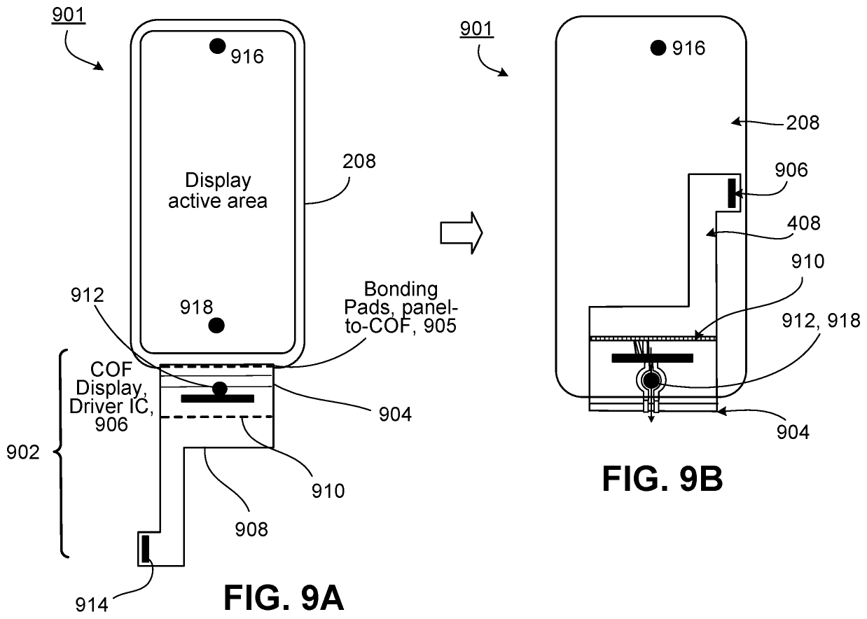

FIG. 9A illustrates a front view of another example display module 901 including (a) the display panel 208, and (b) another interface module 902 (which is an alternate to the interface module 802) that is coupled to the display panel 208 and is to be folded underneath a portion of that display panel 208. The interface module 902 includes a film bending area 904 (which is same as or similar to the film bending area 804), which is not yet folded in the shown configuration. The film bending area 904 is coupled to the panel 208 via a bonding pad 905 (which is same as or similar to the bonding pad 805). The interface module 902 further includes a display driver integrated circuit (IC) 906 (which is same as or similar to the display driver IC 806), a flexible printed circuit board (PCB) 908 (which is same as or similar to the flexible PCB 808), a bonding pad 910 (which is same as or similar to the bonding pad 810) coupling the film area that includes the display driver IC 906 with the flexile PCB 908. The film area that includes the display driver IC 406 further includes an aperture 912 configured to receive the camera module 108. In this implementation, the aperture 912 is above the display driver IC 906 (unlike the aperture 812 which is below the display driver IC 806). The flexible PCB 908 has a connector 914 (which is same as or similar to the connector 814) to connect the display module 901 with other components of the computing device in which it is installed (e.g., for electrical power and control signals from data processing units in the device).

FIG. 9B illustrates a rear view of the display module 901, and shows the interface module 902 that has been folded and placed underneath a portion of the display panel 208. As the aperture is punched when the interface module 802 is folded, the aperture 912 necessarily overlaps with the aperture 918.

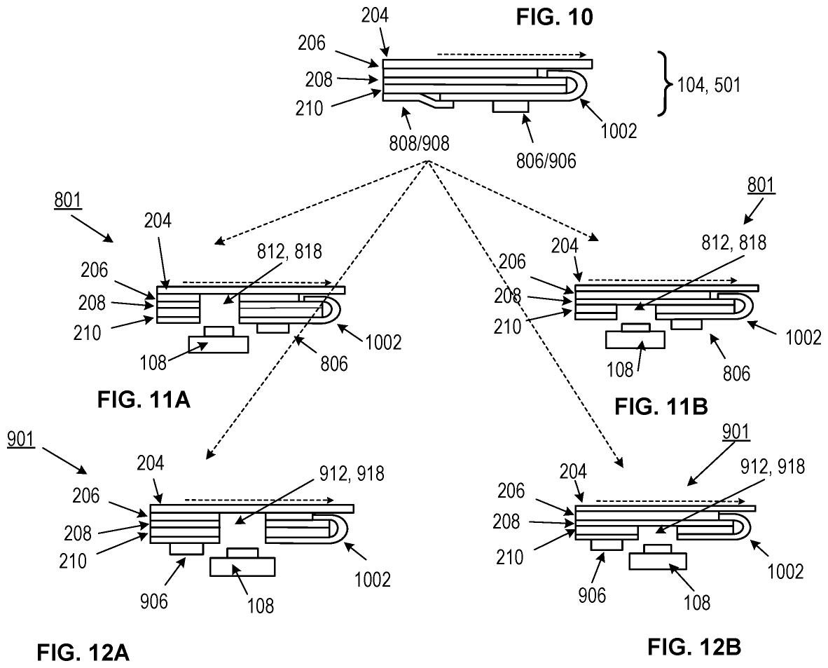

FIG. 10 is a cross-sectional view of an end portion 1001 of a display module 104 at a location where the camera module 108 is to be placed by making/punching an aperture. The punched aperture is shown in FIGS. 8A-9B, which are discussed below. Unlike the display module 104 of FIG. 5 where the panel 208 is folded, the display module 104 of FIG. 10 further includes a film—which can be a film associated with a chip on film (COF) technology, which is also referred to as COF film herein—1002 that is folded instead of the panel 208.

FIG. 11A is a cross-sectional view of an edge portion 501 of the display module 801, which has an aperture 812/818 to accommodate the front-facing camera module 108. In this implementation, the aperture 812/818 is punched through the panel 208 as well as the film 206, back cover (which can include additional cushion sheets) 210 and a folded portion of the film 1002.

FIG. 11B is a cross-sectional view of an edge portion 501 (which is different from the edge portion 201 as shown in FIG. 2) of the display module 801 at a location where the camera module 108 is placed. In this variation, an aperture 812/818 is punched only in the back cover (which can include additional cushion sheets) 210 and the folded portion of the film 1002, but not through the film 206.

FIG. 12A is a cross-sectional view of an edge portion 501 (which is different from the edge portion 201 as shown in FIG. 2) of the display module 901, which has an aperture 912/918 for accommodating the camera module 108. In this variation, an aperture 912/918 is punched through the panel 208, as well as the film 206, back cover (which can include additional cushion sheets) 210, and a folded portion of the film 1002.

FIG. 12B is a cross-sectional view of an edge portion 501 (which is different from the edge portion 201 as shown in FIG. 2) of the display module 901, which has an aperture 912/918 to accommodate the camera module 108. In this variation, the aperture 912 is punched through only the back cover (which can include additional cushion sheets) 210 and the folded portion of the film 1002, but not through the panel 208 or film 206.

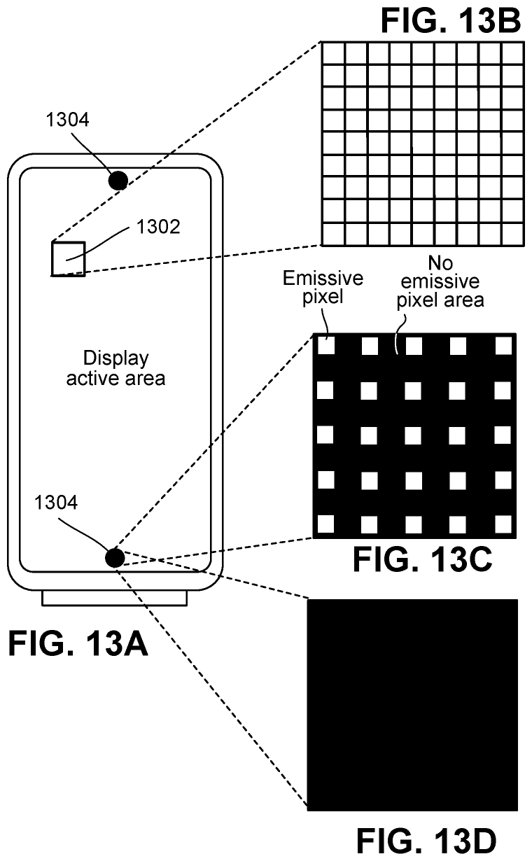

FIGS. 13A-13D show density of emissive pixels in areas where the camera module 108 is placed. When the camera module 108 captures images, the panel 208 at the camera window region 1304 may not be punched through (as described above in FIGS. 6A, 6B, 7A, 7B, 11A, 11B, 12A and 12B) to make an aperture but instead can have a lower density of various components (e.g., metallic elements that form pixel circuits, signal lines, power lines, and OLED electrodes, and/or the like, and may be arranged in one or more patterns) in part of the display active area where the camera window 1304 is located. Such lower density at the area of the camera window 1304 can enable a high transmittance (e.g., transmittance higher than that in other parts of the display active area of the panel) through the camera window 1304 for the camera module to function effectively.

FIG. 13A illustrates a first portion 1302 of the display active area of the panel 208, and a second portion 1304 of that display active area. The second portion 1304 is the area where the camera modules 106 and 108 are placed. FIG. 13B illustrates pixel density for the first portion 1302. FIG. 13C illustrates one alternative implementation of emissive pixel density in the second portion 1304, where a portion of pixel circuits in the camera window region 1304 is removed to increase the transmittance through the panel. FIG. 13D illustrates another alternative implementation where all active pixels in the camera window region 1304 are removed to increase (e.g., maximize) the transmittance. Those two implementations of FIGS. 13C and 13D, which involve removing pixels in the window regions partially or completely, prevent cutting through the display module to create apertures, which, in turn, reduces the non-emissive bezel regions around the camera window 1304 in the display module. While the display panel, the front films, and the cover window are not punched through, any opaque layers on the bottom of the display panel (e.g., back cover films, cushion sheets, etc.) should be punched through to provide the transparent camera window to the cameras.

While all camera modules are described as being fitted within the display active area of the display module, in alternate implementations at least one camera module may be fitted outside the display active area (e.g., the camera module can be fitted in the bezel, notch, or aperture near the edge of the display active area in various implementations). Further, although two camera modules are described as being fitted in a display module per device, the technologies and processes described herein can be expanded/scaled to include any number of camera modules per device, within and/or outside the display active area.

Various implementations of the subject matter described herein can be realized/implemented in digital electronic circuitry, integrated circuitry, specially designed application specific integrated circuits (ASICs), computer hardware, firmware, software, and/or combinations thereof. These various implementations can be implemented in one or more computer programs. These computer programs can be executable and/or interpreted on a programmable system. The programmable system can include at least one programmable processor, which can have a special purpose or a general purpose. The at least one programmable processor can be coupled to a storage system, at least one input device, and at least one output device. The at least one programmable processor can receive data and instructions from, and can transmit data and instructions to, the storage system, the at least one input device, and the at least one output device.

These computer programs (also known as programs, software, software applications or code) can include machine instructions for a programmable processor, and can be implemented in a high-level procedural and/or object-oriented programming language, and/or in assembly/machine language. As can be used herein, the term “machine-readable medium” can refer to any computer program product, apparatus and/or device (for example, magnetic discs, optical disks, memory, programmable logic devices (PLDs)) used to provide machine instructions and/or data to a programmable processor, including a machine-readable medium that can receive machine instructions as a machine-readable signal. The term “machine-readable signal” can refer to any signal used to provide machine instructions and/or data to a programmable processor.

To provide for interaction with a user, the subject matter described herein can be implemented on a computer that can display data to one or more users on a display device, such as a cathode ray tube (CRT) device, a liquid crystal display (LCD) monitor, a light emitting diode (LED) monitor, organic light emitting diode (OLED) device, or any other display device. The computer can receive data from the one or more users via a keyboard, a mouse, a trackball, a joystick, or any other input device. To provide for interaction with the user, other devices can also be provided, such as devices operating based on user feedback, which can include sensory feedback, such as visual feedback, auditory feedback, tactile feedback, and any other feedback. The input from the user can be received in any form, such as acoustic input, speech input, tactile input, or any other input.

Although a few variations have been described in detail above, other modifications can be possible. For example, different alternative implementations can be used either individually or can be combined in any feasible combination. Further, the logic flows described herein may not require the particular order shown, or sequential order, to achieve desirable results. Other implementations may be within the scope of the following claims.

1. A display module comprising:
a plurality of layers including a display panel comprising a display active area and a back cover bonded to the display panel;
a first aperture on a first end of the display active area of the display panel, the first aperture configured to receive a first camera module; and
a second aperture on a second end of the display active area of the display panel, the second aperture configured to receive a second camera module,
wherein a first layer of the plurality of layers is designed to fold around the back cover, the display module comprising a third aperture created by punching two or more layers of the plurality of layers when the first layer is folded around the back cover such that the third aperture aligns with the second aperture, the third aperture designed to receive a second camera module.

2. The display module of claim 1, wherein the first layer is the display panel.

3. The display module of claim 2, wherein:
the plurality of layers further comprise a substrate bonded to the display panel; and
the two or more layers that are punched to create the third aperture comprise the display panel, the back cover, and the substrate.

4. The display module of claim 3, wherein the substrate is a film.

5. The display module of claim 2, wherein the two or more layers that are punched to create the third aperture comprise a portion of the display panel and the back cover.

6. The display module of claim 5, wherein:
the plurality of layers further comprise a substrate bonded to the display panel; and
the two or more layers that are punched to create the third aperture exclude the substrate and another portion of the display panel located between the substrate and the back cover.

7. The display module of claim 2, further comprising:
a display driver integrated circuit that facilitates the display active area of the display panel,
wherein the third aperture is between the display driver integrated circuit and a portion of the display panel that is folded.

8. The display module of claim 2, further comprising:
a display driver integrated circuit that facilitates the display active area of the display panel; and
a flexible printed circuit board connected to the display panel via a bonding pad,
wherein the third aperture is between the display driver integrated circuit and the bonding pad.

9. The display module of claim 1, wherein the first layer is a substrate bonded to the display panel.

10. The display module of claim 9, wherein the substrate is a film.

11. The display module of claim 9, wherein:
the plurality of layers further comprise a substrate bonded to the display panel; and
the two or more layers that are punched to create the third aperture comprise the display panel, the back cover, and the substrate.

12. The display module of claim 9, wherein the two or more layers that are punched to create the third aperture comprise a portion of the substrate and the back cover.

13. The display module of claim 12, wherein the two or more layers that are punched to create the third aperture exclude another portion of the substrate and the display panel.

14. The display module of claim 9, further comprising:
a display driver integrated circuit that facilitates the display active area of the display panel,
wherein the display driver is located on the substrate,
wherein the third aperture is between the display driver integrated circuit and a portion of the display panel that is folded.

15. The display module of claim 9, further comprising:
a display driver integrated circuit that facilitates the display active area of the display panel;
wherein the display driver is located on the substrate,
wherein the substrate is connected to a flexible printed circuit board via a bonding pad,
wherein the third aperture is between the display driver integrated circuit and the bonding pad.

16. An apparatus comprising:
a first aperture on a first end of a display active area of a display panel, the first aperture configured to receive a first camera module;
a second aperture on a second end of the display active area of the display panel, the second aperture configured to receive a second camera module,
wherein each of the first and second ends of the display active area have an emissive pixel density that is lower than the emissive pixel density in other areas of the display active area.
